(19) United States
(12) Patent Application Publication
(10) Pub. No.: US 2012/0000775 A1
(43) Pub. Date: Jan. 5, 2012

(54) Apparatus for Forming Electronic Material Layer

(75) Inventors: Mun Pyo Hong, Gyeonggi-do (KR); Yoo Jong Lee, Seoul (KR); Yun-Sung Jang, Chungcheongnam-do (KR)

(73) Assignee: KOREA UNIVERSITY RESEARCH AND BUSINESS FOUNDATION, Seoul (KR)

(21) Appl. No.: 13/085,723

(22) Filed: Apr. 13, 2011

(30) Foreign Application Priority Data
Jun. 25, 2010 (KR) 1020100060627

(51) Int. Cl. C23C 14/35; C23C 14/08

(52) U.S. Cl. 204/298.13; 204/298.15

(57) ABSTRACT

Disclosed is an apparatus for forming an electronic material layer, in which charged particles damaging the electronic material layer are prevented from arriving at a substrate but processing gas ions maximizing activation of the electronic material layer are accelerated and passed while the electronic material layer is formed on the substrate or the substrate having a functional layer thereon by sputtering, thereby forming the electronic material layer having good electrical/physical characteristics at room temperature.

The apparatus for forming the electronic material layer, the apparatus includes: a chamber where a sputtering process is performed; a sputtering unit which is placed on one inner side of the chamber and mounted with an electronic material layer target; a holding unit which is placed on a side opposite to the one inner side of the chamber where the sputtering unit is placed, and mounted with an object on which an electronic material layer is formed; and a limiter which is placed between the sputtering unit and the holding unit, and generates a magnetic filed in a direction perpendicular to a moving direction of ions and electrons generated in a sputtering process.

### CROSS-REFERENCE TO RELATED APPLICATION

This application claims priority to and the benefit of Korean Patent Application No. 10-2010-0060627 filed in the Korean Intellectual Property Office on Jun. 25, 2010, the entire contents of which are incorporated herein by reference.

### BACKGROUND OF THE INVENTION

(a) Field of the Invention

The present invention relates to an apparatus for forming an electronic material layer, and more particularly, to an apparatus for forming an electronic material layer, in which charged particles damaging the electronic material layer are prevented from arriving at a substrate but processing gas ions maximizing activation of the electronic material layer are accelerated and passed while the electronic material layer is formed on the substrate or the substrate having a functional layer thereon by sputtering, thereby forming the electronic material layer having good electrical/physical characteristics at room temperature.

(b) Description of the Related Art

Transparent conductive oxide (TCO) has been used as a representative transparent electrode material for very various semiconductor devices, display devices, solar devices, etc.

Generally, the most common process of growing a TCO thin film is a deposition process using a sputtering technique. The sputtering technique, which is the easiest way to acquire productivity, stability and characteristics of the thin film, may need additional high-temperature heat treatment in accordance with materials of the TCO thin film.

In particular, an indium tin oxide (ITO) thin film is known for the most excellent transmittance and conductivity among the TCO thin films, i.e., transmittance of 85% or more and excellent resistivity of 5×10⁻⁴Ω·cm or less, but surely has to undergo the additional high-temperature heat treatment of 200□ to 300□ for the characteristics of the thin film when deposited using the sputtering technique.

However, the high-temperature heat treatment may very fatally damage a plastic substrate, and thus unsuitable for a method of manufacturing a flexible electronic device based on a plastic substrate. To solve this, there is a desperate need of developing a new process for forming a TCO thin film and forming an electrode at room temperature or low temperature.

Such a process for forming a high property TCO thin film at room temperature without any additional heat treatment is really necessary for not only the flexible electronic device based on the plastic substrate but also an organic light emitting device and an organic solar cell using a plasma buffer layer and a layer having the same function as the plasma buffer layer.

Particularly, a transparent electrode used for the flexible electronic device has to satisfy durability against flexible characteristics. Thus, the durability against the flexibility of the transparent electrode is very important, and therefore there has to be developed a process of forming a TCO thin film that has a nano-crystal structure capable of satisfying both high conductivity and high durability against the flexibility.

In the case of growing the TCO thin film through the sputtering technique at a room temperature range, a new process of effectively preventing a TCO thin film from being physically damaged by negative oxygen ions (O2⁻) that have very high energy and are generated during most of sputtering procedures for the TCO thin film is required prior to forming the high property transparent electrode satisfying the above characteristics.

Besides, it is required to develop a process of more effectively supplying energy for activating/crystallizing a TCO thin film based on sputtering gas ions (e.g., Ar⁺) instead of the additional high temperature heat treatment.

However, there has not been hitherto proposed a technology for preventing the thin film from being damaged by the negative oxygen ions generated during the sputtering procedure and having high energy, and maximizing the activation/crystallization for the tin film based on the processing gas ions.

### SUMMARY OF THE INVENTION

Accordingly, the present invention is conceived to solve the forgoing problems, and an aspect of the present invention is to provide an apparatus for forming an electronic material layer, in which charged particles damaging the electronic material layer are prevented from arriving at a substrate but processing gas ions maximizing activation of the electronic material layer are accelerated and passed while the electronic material layer is formed on the substrate or the substrate having a functional layer thereon by sputtering, thereby forming the electronic material layer having good electrical/physical characteristics at room temperature.

An exemplary embodiment of the present invention provides an apparatus for forming an electronic material layer, the apparatus including: a chamber where a sputtering process is performed; a sputtering unit which is placed on one inner side of the chamber and mounted with an electronic material layer target; a holding unit which is placed on a side opposite to the one inner side of the chamber where the sputtering unit is placed, and mounted with an object on which an electronic material layer is formed; and a limiter which is placed between the sputtering unit and the holding unit, and generates a magnetic filed in a direction perpendicular to a moving direction of ions and electrons generated in a sputtering process.

The limiter may include a magnet array where magnet pairs formed by coupling an N-pole magnet with an S-pole magnet are spaced apart from each other to form a slit; and a holding frame which holds the magnet array and is attached to an inside of the chamber.

The slit may have a long axis perpendicular to a long axis of the electronic material layer target.

The holding unit may be configured to reciprocate within the chamber. The holding unit may have a reciprocating direction perpendicular to the long axis of the slit.

The electronic material layer target may include a transparent conductive oxide (TCO) material.

The electronic material layer target may include an indium tin oxide (ITO) material.

Processing gas used in the sputtering process may include one of Ar, Xe, Kr, N₂ and He.

The object may include a plastic substrate or a substrate coated with a functional layer thereon.

The object may include a substrate for an organic light emitting device formed with a plasma buffer layer on a top thereof.

The object may include a substrate for an organic solar cell formed with a plasma buffer layer on a top thereof.

Electrons generated during the sputtering process may be restrained by the magnetic field and form negative electric potential around the magnet array of the limiter.

The negative electric potential may prevent negative oxygen ions generated in the electronic material layer target from traveling toward the object during the sputtering process.

The negative electric potential may accelerate and pass ions generated during the sputtering process.

### BRIEF DESCRIPTION OF THE DRAWINGS

The above and/or other aspects of the present invention will become apparent and more readily appreciated from the following description of the exemplary embodiments, taken in conjunction with the accompanying drawings, in which:

FIG. 1 is a schematic view showing an apparatus for forming an electronic material layer according to an exemplary embodiment of the present invention;

FIG. 2 is a schematic view showing a limiter applied to the present invention;

FIG. 3 is a schematic view showing reciprocating motion of a holding unit applied to the present invention;

FIG. 4 is a schematic view showing an example of a direction of a magnetic field of the limiter applied to the present invention and a moving direction of an electronic material layer solid element;

FIG. 5 shows an example of negative electric potential generated around the limiter applied to the present invention;

FIG. 6 shows an example of a situation where negative oxygen ions are blocked out by the negative electric potential applied to the present invention;

FIG. 7 shows an example of a situation where processing gas ions are accelerated and passed by the negative electric potential applied to the present invention;

FIG. 8 is a graph where the electric characteristics of the electronic material layer manufactured according to an exemplary embodiment of the present invention is compared with that of an ITO thin film manufactured by the conventional sputtering technique; and

FIG. 9 is a graph showing measured atomic function microscope (AFM) data and X-ray diffraction (XRD) data of the electronic material layer manufactured according to an exemplary embodiment of the present invention.

### DETAILED DESCRIPTION OF THE EMBODIMENTS

Hereinafter, an electronic material layer according to exemplary embodiments of the present invention will be described with reference to the accompanying drawings.

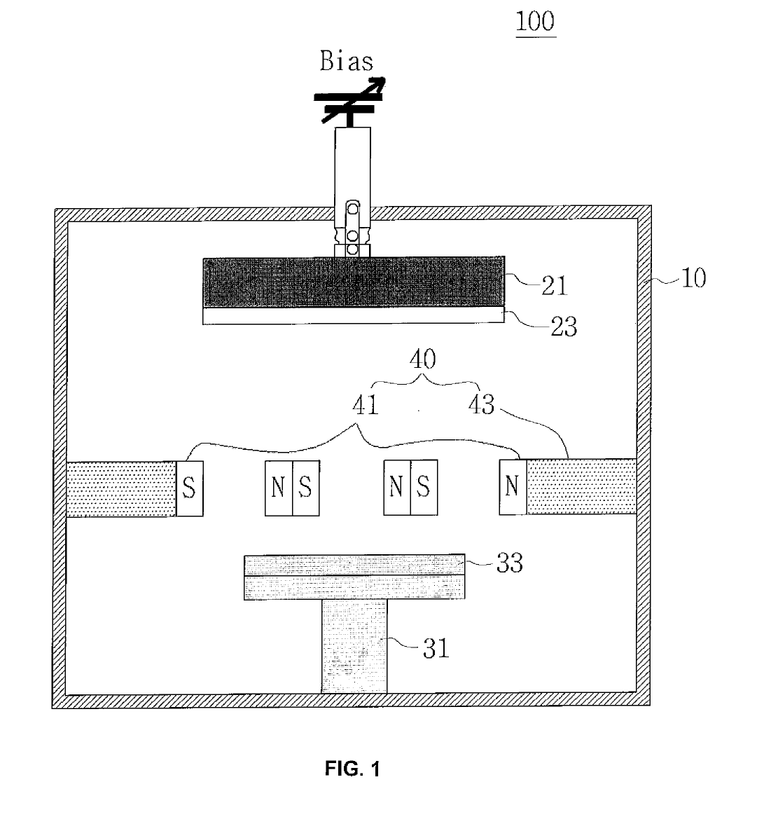

FIG. 1 is a cross-section view of an apparatus for forming an electronic material layer according to an exemplary embodiment of the present invention. As shown in FIG. 1, an apparatus 100 for forming an electronic material in this exemplary embodiment includes a chamber 10, a sputtering unit 21 mounted with an electronic material layer target 23, a holding unit 31 mounted with an object 33 on which the electronic material layer is formed, and a limiter 40 generating a magnetic field.

The chamber 10 is a space where a sputtering process is performed, which is formed to be isolated from the exterior. The sputtering process is performed within the chamber 10, and it will be thus appreciated that a pumping port (not shown) for vacuum, processing gas introducing and discharging ports (not shown), and the like are formed in the chamber 10.

The sputtering unit 21 is fixed and disposed on one inner side of the chamber 10 as shown in FIG. 1. Further, the sputtering unit 21 is mounted with the electronic material layer target 23 is mounted. In other words, the sputtering unit 21 is fastened to one inner side of the chamber 10 so that it can receive a predetermined bias voltage and causes the electronic material layer target 23 to do a sputtering operation.

Referring to FIG. 1, only one sputtering unit 21 mounted with the electronic material layer target 23 is placed inside the chamber 10, but not limited thereto. Alternatively, two sputtering units may be spaced apart from each other and placed inside the chamber 10.

In the case that only one sputtering unit 21 is placed inside the chamber 10, the electronic material layer target 23 mounted to the sputtering unit 21 is disposed in parallel with the object 33 mounted to the holding unit 31. In the case that two sputtering units 21 are placed inside the chamber 10, the electronic material layer targets 23 respectively mounted to the sputtering units 21 are disposed and inclined at a predetermined angle to the object mounted to the holding unit 31.

As shown in FIG. 1, if the sputtering unit 21 is fixed and placed on one inner side of the chamber 10, e.g., on an inner upside of the chamber 10, the holding unit 31 is placed on an inner downside of the chamber 10. That is, the holding unit 31 is placed on a side opposite to the one inner side of the chamber 10 where the sputtering unit 21 is placed.

The holding unit 31 placed inside the chamber 10 at the opposite side to the sputtering unit 21 is mounted with the object 33 on which the electronic material layer is formed. That is, electronic materials sputtered from the electronic material layer target 23 are deposited on the object 33 and form the electronic material layer, in which the object 33 is mounted on to the holding unit 31.

Meanwhile, the limiter 40 is provided between the sputtering unit 21 and the holding unit 31. The limiter 30 generates a magnetic field in a direction perpendicular to the moving direction of ions and electrons generated in the sputtering process (i.e., perpendicular to a direction from the electronic material layer target 23 to the object 33).

The reason why the limiter 40 generates the magnetic field in the direction perpendicular to the moving direction of the ions and electrons generated during the sputtering process is to block out the electrons damaging the electronic material layer formed on the object 33 and accelerate and pass the ions for activating the electronic material layer.

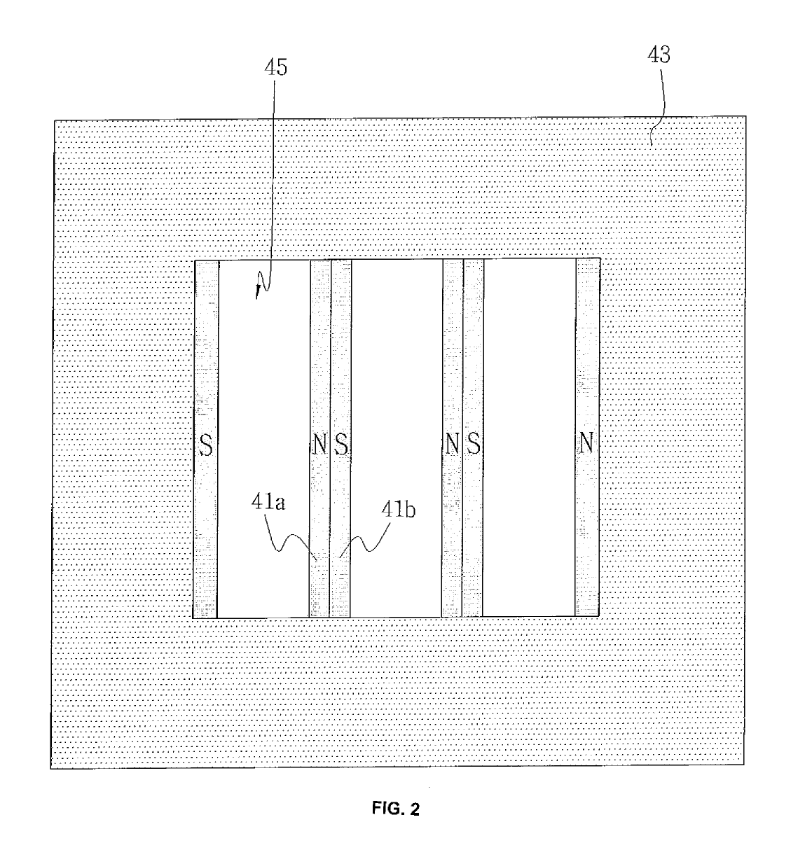

In order to generate the magnetic field, the limiter 40 includes magnets arranged following a certain rule, which will be described with reference to FIG. 2.

FIG. 2 is a plan view showing the limiter 40. As shown in FIG. 2, the limiter includes a magnet array 41, and a holding frame 43 holding the magnet array 41 and attached to the inside of the chamber 10.

Referring to FIG. 2, the magnet array 41 constituting the limiter 40 forms a slit 45 since magnet pairs formed by coupling an N-pole magnet 41a with an S-pole magnet 41b are spaced apart from each other.

Specifically, the N-pole magnet 41a and the S-pole magnet 41b are attached to form the magnet pair, and the magnet pairs are spaced apart from each other, thereby forming the magnet array 41. As the magnet pairs are spaced apart from each other, the slit 45 is formed. The magnet array 41 is fastened by the holding frame 43. That is, the holding frame 43 holds the magnet array 41 and is attached and installed on the inside of the chamber 10.

In the magnet array 41, the magnet pairs formed by coupling the N-pole magnet 41a and the S-pole magnet 41b are spaced apart from each other, but the magnets arranged at opposite edges are not the magnet pair of the N-pole magnet 41a and the S-pole magnet 41b but respectively the N-pole magnet and the S-pole magnet as shown in FIGS. 1 and 2.

The electronic materials sputtered from the electronic material layer target 23 are deposited on the object 33 mounted on the holding unit 31 through the slit 45 formed in the limiter 40. To effectively deposit the electronic materials on the object through the slit 45 of the limiter 40, the slit 40 may be formed to have a long axis perpendicularly to the long axis of the electronic material layer target 23. That is, as shown in FIG. 1, the long axis of the electronic material layer target 23 (i.e., the axis of the electronic material layer target shown in the drawing) is formed perpendicularly to the long axis of the slit 45 (i.e., the axis in the direction of penetrating the drawing, that is, a vertical axis in the slit 45 of FIG. 2).

Meanwhile, the limiter 40 includes the magnet array 41, so that the electronic materials cannot be uniformly deposited on the object 33. Therefore, according to an exemplary embodiment of the present invention, the object 33 is configured to reciprocate so that the electronic materials can be uniformly deposited on the object 33.

Specifically, the holding unit 31 mounted with the object 33 can reciprocate within the chamber 10. The reciprocation of the holding unit 31 can be achieved by combining additional elements (motor, rail, etc.)

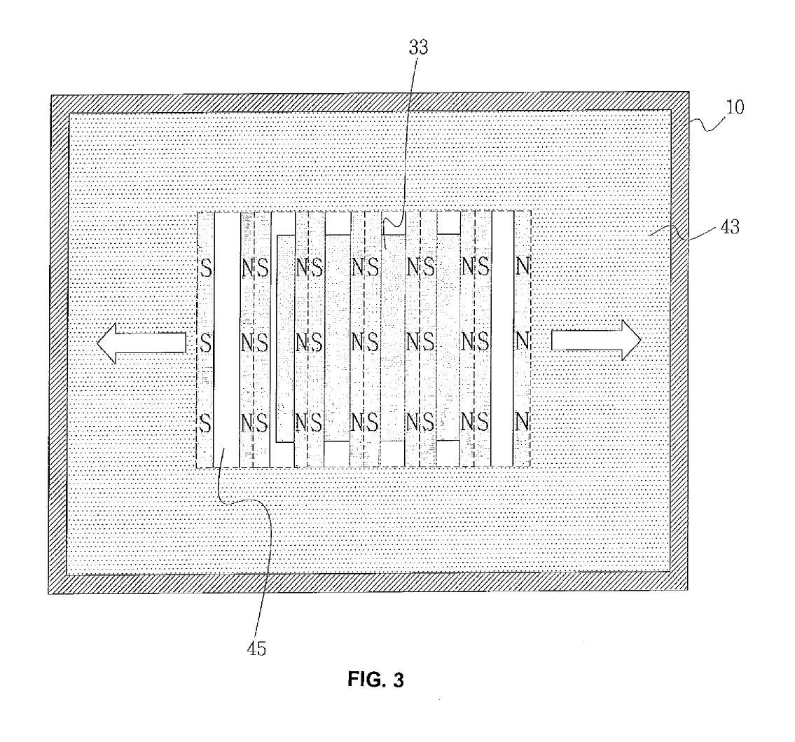

FIG. 3 is a plan view showing a reciprocating direction of the holding unit 31. As shown in FIG. 3, the reciprocating direction (arrow) of the holding unit 31 is perpendicular to the long axis of the slit 45. If the holding unit 31 reciprocates in such a direction, the electronic material layer can be deposited even on a top part of the object where the magnet array obstructs the deposition of the electronic material.

With the foregoing apparatus for forming the electronic material layer, a process of forming the electronic material layer on the object 33 will be described as follows.

Basically, the following exemplary embodiments include a process of employing the limiter 40 for blocking out negative oxygen ions sputtered by the electronic material layer target 23 and having high energy, but accelerating and passing processing gas ions to supply higher activation/crystallization energy to the electronic material layer while depositing the electronic material layer on the basis of a sputtering method, in which electrons in a plasma state are restrained by the magnetic filed of the limiter 40 using the magnet array 41 and have negative electric potential. This process is performed while depositing the electronic material layer, thereby forming the electronic material layer.

According to this method, it is possible to form a high property electronic material layer having a nano-crystal structure even at room temperature, and there is no need of additional heat treatment so that this method can be effectively applied to an electronic device using a plastic substrate and an organic electronic device such as an organic light emitting device, an organic solar cell, etc. using a plasma buffer layer and a layer having the same function.

In the following exemplary embodiments, indium tin oxide (ITO) will be described as an example of an electronic material required to have low electric resistance and high optical transmittance. Alternatively, such an electric material may include TCO materials such as indium zinc oxide (IZO), indium zinc tin oxide (IZTO), aluminum zinc oxide (AZO), etc. Further, Ar gas of representative unreactive gas will be described as the processing gas for plasma and sputtering. Alternatively, the processing gas may include any gas for the plasma, such as Ar, Xe, Kr, N₂, He, etc. However, the foregoing certain TCO material and plasma gas do not limit the technical scope of the present exemplary embodiment.

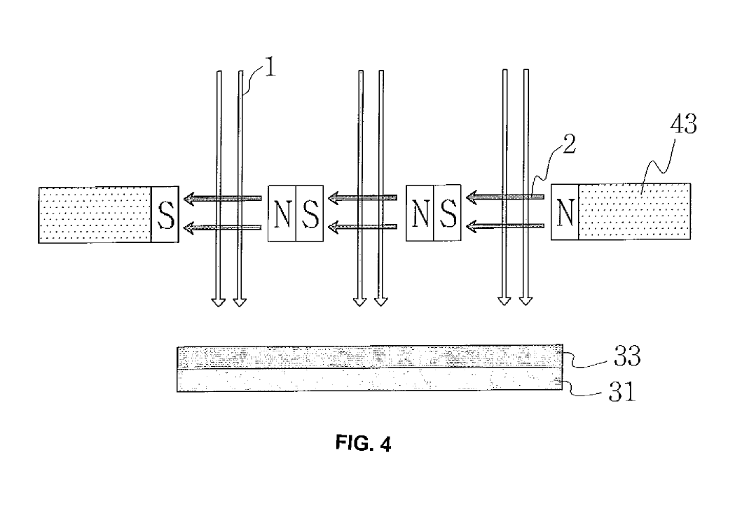

As shown in FIG. 4, the electronic material layer is formed on the object 33. At this time, the electronic material layer is formed by the sputtering method, and the limiter 40 using the magnet array to generate the magnetic field in a parallel with the object 33 is disposed on a path 1 of depositing the solid element for the electronic material layer to separate the object 33 from plasma.

Since most of sputtered solid elements for the electronic material layer are neutral particles, they can be deposited on the object 33 without being affected by the magnetic field of the limiter 40. However, if the limiter 40 is used as above, there is made a shadow region at which the sputtered sold elements cannot arrive. To prevent this, the object 33 reciprocates in a direction perpendicular to the long axis of the rectangular slit 45 located between the magnet pairs of the limiter 40, so that uniform deposition can be achieved throughout the whole target areas of the object 33.

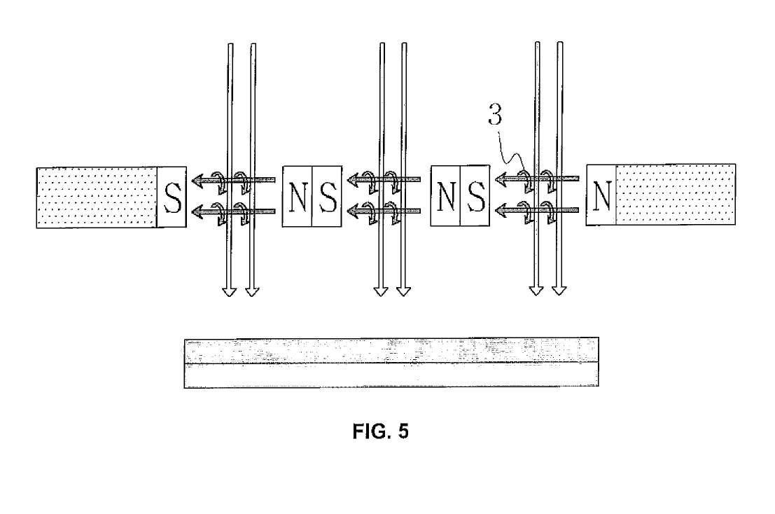

As shown in FIG. 5, electrons in the plasma state while depositing the electronic material layer by the sputtering method has so light weight that they are restrained in the magnetic field 2 generated by the limiter 40. The restrained electrons have mirror motion within the magnetic field, and thus the limiter 40 has negative electric potential 3. In this process, the sputtered solid elements for the electronic material layer are electrically neutral and free from the influence of the negative electric potential 3.

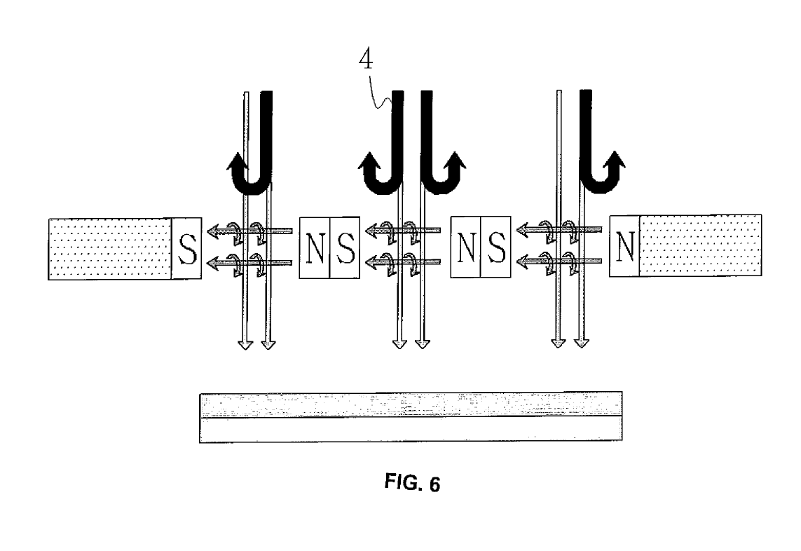

As shown in FIG. 6, the limiter 40 charged with the negative electric potential may cause negative oxygen ions 4 generated in the electronic material layer solid element target and having very high energy not to arrive at the object 33 or to decelerate and arrive with very low energy.

In a general sputtering process, negative oxygen ions are generated in the solid element target while depositing a transparent conductive oxide thin film. Such negative oxygen ions are accelerated by difference in potential applied between a cathode target and an anode electrode, and collides with the deposited thin film by very high energy (e.g., hundreds of eV or more), thereby physically damaging the thin film. Referring to FIG. 6, the limiter 40 can serve to very largely decrease or block out the physical collision energy of the negative oxygen ions.

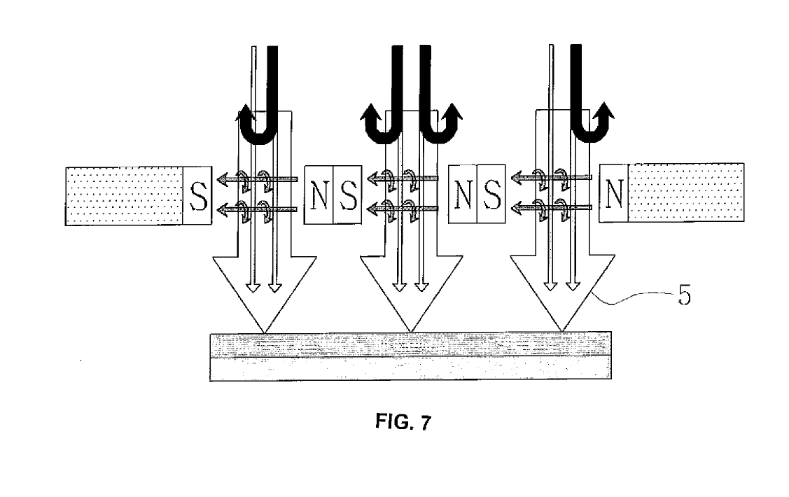

Referring to FIG. 7, the Ar ions 5 used as the sputtering processing gas are accelerated to supply greater activation and crystallization energy to the growing electronic material layer. In general, sputtered gas enters a plasma state and is ionized during the sputtering process.

In a general sputtering process for the transparent conductive oxide thin film, energy needed for activating and crystallizing the transparent conductive oxide thin film is supplied by Ar⁺ ions in the plasma state. However, the Ar⁺ ions introduced into the thin film at this time has so low energy of about several eV that enough energy cannot be supplied to the growing thin film.

However, a negative charged limiter 201 accelerates the Ar⁺ ions with higher energy so that the activation and crystallization energy greater than that of the general sputtering process can be supplied to the growing thin film.

The process of forming the electronic material layer where the foregoing electric characteristics are reflected is as follows.

First, unreactive plasma processing gas is introduced into the chamber 10. The processing gas used in the sputtering process may be one of Ar, Xe, Kr, N₂ and He.

The introduced processing gas is transformed into plasma through plasma discharging in the chamber 10. Then, a predetermined bias voltage is applied to the sputtering unit 21 of the chamber 10 by plasma, so that Ar⁺ ions can collide with the electronic material layer target 23, thereby sputtering the solid elements for the electronic material layer to a plasma chamber space.

Next, the solid elements for the electronic material layer are induced toward the vicinity of the object 33, to thereby form the electronic material layer on the surface of the object 33. At this time, the limiter 40 is disposed on a traveling path of the solid elements for the electronic material layer, so that the object 33 can be separated from the plasma. Such deposition of the electronic material layer may be implemented at room temperature equal to or lower than 50° C.

In this process, the limiter 40 generates the magnetic field within the slit by the magnet array, and the generated magnetic field restrains the electrons of already generated plasma. The restrained electrons do the mirror motion within the magnetic filed, and charges the limiter 40 with the electric potential.

The limiter 40 charged with the negative electric potential prevents the negative oxygen ions, which are generated together with the solid elements for the electronic material layer and accelerated by difference in electric potential as much as a predetermined bias applied to the sputtering unit 21, from traveling toward the substrate, or decelerates the negative oxygen ions to have very low energy.

The Ar⁺ ions already generated in the chamber 10 are accelerated to have higher energy by the limiter 40 charged with the negative electric potential, and the accelerated Ar⁺ ions supplies higher activation/crystallization energy to the growing electronic material layer thin film.

Through the above process, it is possible to form the high characteristic electronic material thin film having very high electric conductivity at room temperature equal to or less then 50° C. Such a method of forming the electronic material layer may be applied to any electronic device using the plastic substrate on which a transparent conductive oxide electrode is formed, and used for an organic light emitting device, an organic solar cell, etc. using a buffer layer for plasma, and a layer having the same function.

Accordingly, the foregoing electronic material layer target may be made of a transparent conductive oxide material (TCO). In this case, the electronic material layer target may include an indium tin oxide (ITO) material.

Meanwhile, the object 33 on which the electronic material layer is formed may be various substrates or electronic devices.

That is, the object may be a plastic substrate or a substrate coated with a functional layer thereon. In this case, the electronic material layer is deposited on the plastic substrate or the substrate coated with the functional layer thereon.

Also, the object may be a substrate for an organic light emitting device formed with a plasma buffer layer on the top thereof. In this case, the electronic material layer is deposited on the substrate for the organic light emitting device formed with the plasma buffer layer on the top thereof.

Further, the object may be a substrate for an organic solar cell formed with a plasma buffer layer on the top thereof. In this case, the electronic material layer is deposited on the substrate for the organic solar cell formed with to the plasma buffer layer on the top thereof.

Meanwhile, as described above, the electrons generated during the sputtering process are restrained by the magnetic field and thus form the negative electric potential around the magnet array of the limiter.

Further, during the sputtering process, the negative electric potential prevents the negative oxygen ions generated in the electronic material layer target from moving toward the object, and accelerates and passes the ions generated during the sputtering process.

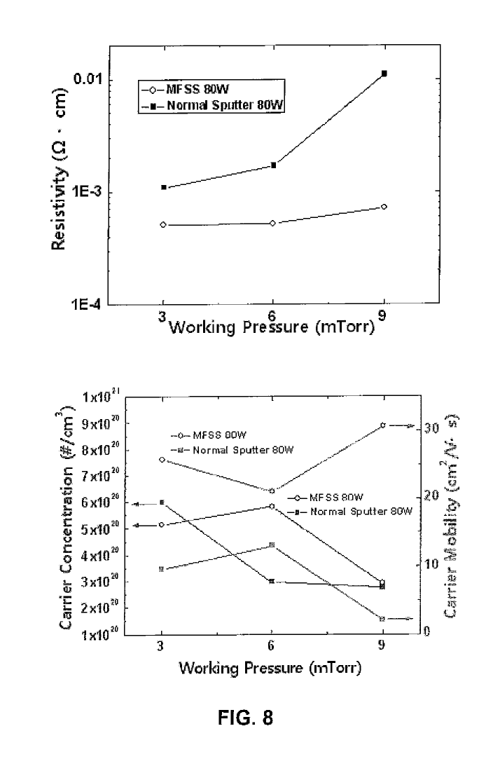

FIG. 8 is a graph where the electric characteristics of the electronic material thin film (ITO thin film) manufactured according to the foregoing exemplary embodiment of the present invention is compared with that of an ITO thin film deposited by a general sputtering method, in which resistivity, carrier density and mobility are varied depending on deposition pressure.

Through this graph, it will be understood that the resistivity of the ITO thin film deposited according to an exemplary embodiment of the present invention is lowered by 50% or more throughout all the deposition pressure, and variance in the mobility is significant as a factor affecting difference in the resistivity of the thin film.

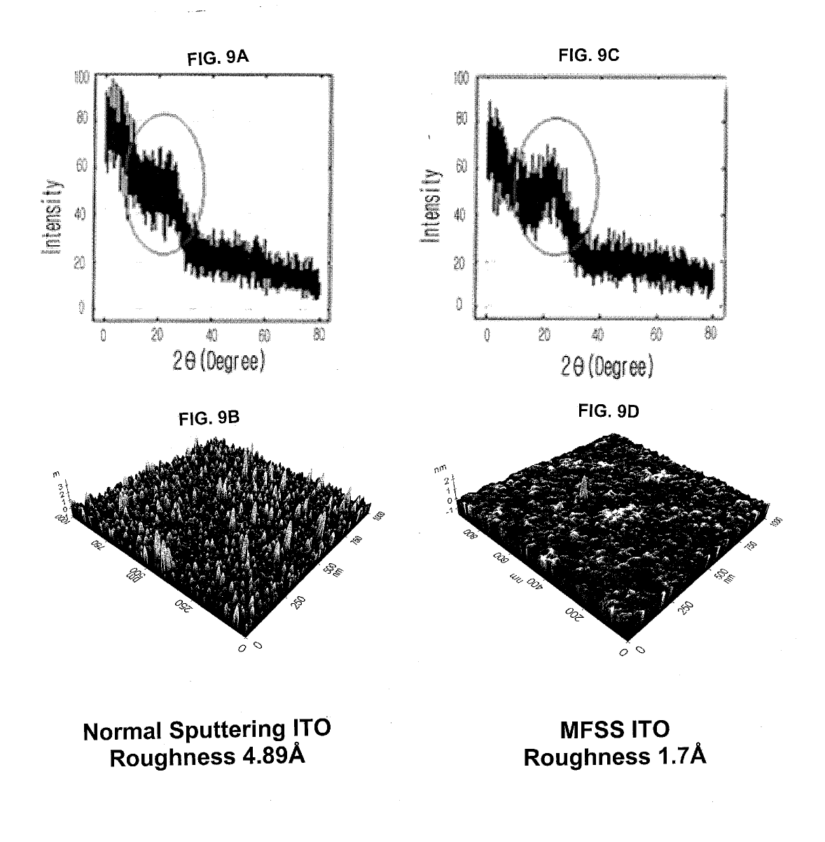

FIG. 9 shows measured atomic function microscope (AFM) data and X-ray diffraction (XRD) data of the electronic material layer manufactured according to an exemplary embodiment of the present invention. It will be appreciated that the ITO thin film manufactured according to an exemplary embodiment of the present invention has roughness three or more times lower than the roughness of the ITO thin film deposited by the general sputtering process under the same condition. On the contrary to the XRD data of the ITO thin film based on the general sputtering process, it will be also appreciated that a weak crystallization peak of a ‘222’ direction, which can be representatively ascertained in the crystallized ITO thin film, is formed.

In accordance with data of FIGS. 8 and 9, the apparatus for forming the electric material layer according to an exemplary embodiment of the present invention effectively blocks out the negative oxygen ions generated in the transparent conductive oxide solid element target and having high energy, and effectively supplies energy for activating/crystallizing the thin film through the sputtering gas ions (Ar⁺), thereby forming an ITO transparent electrode having a very excellent nano-crystal structure at room temperature.

As apparent from the above description, there is provided an apparatus for forming an electronic material layer, in which charged particles damaging the electronic material layer are prevented from arriving at a substrate but processing gas ions maximizing activation of the electronic material layer are accelerated and passed while the electronic material layer is formed on the substrate or the substrate having a functional layer thereon by sputtering, so that the electronic material layer having good electrical/physical characteristics can be advantageously formed at room temperature.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An apparatus for forming an electronic material layer, the apparatus comprising:
a chamber where a sputtering process is performed;
a sputtering unit which is placed on one inner side of the chamber and mounted with an electronic material layer target;
a holding unit which is placed on a side opposite to the one inner side of the chamber where the sputtering unit is placed, and mounted with an object on which an electronic material layer is formed; and
a limiter which is placed between the sputtering unit and the holding unit, and generates a magnetic filed in a direction perpendicular to a moving direction of ions and electrons generated in a sputtering process.

2. The apparatus according to claim 1, wherein
the limiter comprises
a magnet array where magnet pairs formed by coupling an N-pole magnet with an S-pole magnet are spaced apart from each other to form a slit; and
a holding frame which holds the magnet array and is attached to an inside of the chamber.

3. The apparatus according to claim 2, wherein the slit has a long axis perpendicular to a long axis of the electronic material layer target.

4. The apparatus according to claim 2, wherein the holding unit is configured to reciprocate within the chamber.

5. The apparatus according to claim 4, wherein the holding unit has a reciprocating direction perpendicular to the long axis of the slit.

6. The apparatus according to claim 1, wherein the electronic material layer target comprises a transparent conductive oxide (TCO) material.

7. The apparatus according to claim 6, wherein the electronic material layer target comprises an indium tin oxide (ITO) material.

8. The apparatus according to claim 1, wherein processing gas used in the sputtering process comprises one of Ar, Xe, Kr, N₂ and He.

9. The apparatus according to claim 1, wherein the object comprises a plastic substrate or a substrate coated with a functional layer thereon.

10. The apparatus according to claim 1, wherein the object comprises a substrate for an organic light emitting device formed with a plasma buffer layer on a top thereof.

11. The apparatus according to claim 1, wherein the object comprises a substrate for an organic solar cell formed with a plasma buffer layer on a top thereof.

12. The apparatus according to claim 2, wherein electrons generated during the sputtering process are restrained by the magnetic field and form negative electric potential around the magnet array of the limiter.

13. The apparatus according to claim 12, wherein the negative electric potential prevents negative oxygen ions generated in the electronic material layer target from traveling toward the object during the sputtering process.

14. The apparatus according to claim 12, wherein the negative electric potential accelerates and passes ions generated during the sputtering process.
